(19) United States
(12) Patent Application Publication
(10) Pub. No.: US 2026/0236417 A1
(43) Pub. Date: Aug. 13, 2026

(54) AUXILIARY SENSING AND CONTROL SYSTEM FOR SEMICONDUCTOR EQUIPMENT AND SENSING AND CONTROL METHOD USING THE SAME

(71) Applicant: SAMSUNG ELECTRONICS CO., LTD., Suwon-si (KR)

(72) Inventors: Changwoo SON, Suwon-si (KR); Beomgyu HEO, Suwon-si (KR); Kyoungwhan CHA, Anyang-si (KR); Sungwoo JUNG, Anyang-si (KR); Mingyu JUNG, Anyang-si (KR); Daehyun LIM, Anyang-si (KR); Woohyung KIM, Suwon-si (KR); Byunghi KIM, Anyang-si (KR); Sunho KIM, Suwon-si (KR)

(73) Assignee: SAMSUNG ELECTRONICS CO., LTD., Suwon-si (KR)

(21) Appl. No.: 19/460,555

(22) Filed: Jan. 27, 2026

(30) Foreign Application Priority Data
Feb. 13, 2025 (KR) 10-2025-0019010

(51) Int. Cl. G06F 13/36

(52) U.S. Cl. CPC G06F 13/36; G06F 2213/40

(57) ABSTRACT

An auxiliary sensing and control system for semiconductor equipment, includes a sensor and automation module including an automation device and a sensor additionally installed in the semiconductor equipment, a sensor and automation device control module for controlling the sensor and automation module, and a data integration operation module for controlling trace data of the semiconductor equipment and data acquired by the automation device of the sensor and automation module to a host system, and receiving and processing a control signal of the host system.

### CROSS-REFERENCE TO RELATED APPLICATION

This application is based on and claims priority under 35 U.S.C. § 119 to Korean Patent Application No. 10-2025-0019010, filed on Feb. 13, 2025, in the Korean Intellectual Property Office, the disclosure of which is incorporated by reference herein in its entirety.

### BACKGROUND

The inventive concept relates to an auxiliary sensing and control system for semiconductor equipment and a sensing and control method using the same, and more particularly, to an auxiliary sensing and control system for semiconductor equipment, which transmits data measured by sensors additionally installed in the existing semiconductor equipment to a control sensor while converting existing semiconductor equipment communications standard 1 (SECS-I)-based signals to high-speed SECS message services (HSMS)-based signals, to clearly understand the process status of the semiconductor equipment, and a sensing and control method using the same.

The semiconductor equipment is equipped with sensors to measure various types of values according to the equipment. The measured values are monitored in real time to determine whether the process is proceeding under appropriate conditions. The sensors include the following:
a temperature sensor used for controlling the temperature of a wafer;
a pressure sensor used for monitoring the internal pressure of a chamber during a deposition process or an etching process;
a gas sensor for detecting the concentration of gases used in a chemical vapor deposition process or an etching process;
a particle sensor for detecting the number of fine particles in the air in a cleanroom environment;
a vibration sensor for monitoring the vibration status of equipment;
an optical sensor used for checking pattern alignment and exposure accuracy in a lithography process;
a thickness measurement sensor for measuring the thickness of a deposited film in real time; and
a humidity sensor for monitoring the humidity inside the cleanroom.

The latest equipment is equipped with sensors necessary for monitoring a process, but older equipment may require sensors that were not necessary at the time of installation as technology advances. However, in many cases, the equipment manufacturer does not add the necessary sensors. There are even cases where the equipment manufacturer goes bankrupt and additional equipment cannot even be requested.

The older equipment often uses semiconductor equipment communications standard 1/generic equipment model protocol (SECS/GEM)-based communication via a serial interface (I/F) to transmit values measured by sensors in real time.

The serial I/F refers to an interface that transmits data serially, and the serial I/F has the advantage of being suitable for long-distance communication by transmitting data sequentially, one bit at a time, and being able to be implemented with simple hardware due to the small number of signal lines.

However, since the serial I/F transmits one bit at a time, the transmission speed is slow, compared to a parallel interface, thereby causing a bottleneck, especially when transmitting large amounts of data. Synchronous communication can increase complexity because the synchronous communication requires a clock signal to accurately synchronize data transmission and reception, while asynchronous communication incurs additional overhead because the asynchronous communication requires synchronization with start and stop bits. Some serial interfaces, such as RS-232, can become susceptible to signal attenuation and noise as the distance increases, requiring signal amplification devices or separate communication equipment when long-distance transmission is required.

A new problem may arise from the aforementioned drawbacks. When installing new sensors on older equipment, a separate communication line must be installed for serial I/F communication (wired communication) to transmit the measured values to the control center. Due to reasons, such as interference with already installed equipment, it is difficult to install new communication lines that were not included in the overall design of the process.

### SUMMARY

The inventive concept provides an auxiliary sensing and control system for semiconductor equipment capable of effectively communicating measurement results of new sensors and sensors installed in the existing processing equipment to the host system while installing new sensors in aging semiconductor equipment, and a sensing and control method using the same.

According to an aspect of the inventive concept, there is provided an auxiliary sensing and control system for semiconductor equipment, including a sensor and automation module including an automation device and a sensor additionally installed in the semiconductor equipment, a sensor and automation device control module configured to control the sensor and automation module, and a data integration operation module configured to transmit trace data of the semiconductor equipment and data acquired by the automation device of the sensor and automation module to a host system, and to receive and to process a control signal of the host system.

According to another aspect of the inventive concept, there is provided an auxiliary sensing and control system for semiconductor equipment, including a sensor and automation module including an automation device and a sensor additionally installed in the semiconductor equipment, a sensor and automation device control module configured to control the sensor and automation module, a data integration operation module configured to transmit trace data of the semiconductor equipment and data acquired by the sensor and the automation device of the sensor and automation module to the host system, and to receive and to process a control signal of the host system, a conversion module configured to convert a semiconductor equipment communications standard (SECS) signal and a high-speed SECS message services (HSMS) signal, and a sensor data management module configured to manage and operating a status variable identification (SVID) and a newly registered SVID of the semiconductor equipment, wherein the sensor and automation device control module is configured to receive and to hold a value obtained by converting the SECS data into a DataFrame, to control the sensor and automation module based on the received DataFrame, and to receive a control result of the sensor and automation module and to return the control result to the data integration operation module, and the semiconductor equipment and the host system perform synchronous communication for transmitting and receiving trace data of the semiconductor equipment at regular intervals, or perform irregular asynchronous communication.

According to another aspect of the inventive concept, there is provided a sensing and control method for semiconductor equipment, including requesting trace data, in which a data integration operation module transmits a trace data request signal of the semiconductor equipment, generating and transmitting trace data, wherein the trace data is generated upon receiving the trace data request signal, and transmitted to the data integration operation module, and reporting the trace data wherein the data integration operation module transmits the received trace data to a host system.

### BRIEF DESCRIPTION OF THE DRAWINGS

Embodiments will be more clearly understood from the following detailed description taken in conjunction with the accompanying drawings in which:

FIG. 1 is a block diagram of an auxiliary sensing and control system for semiconductor equipment, according to a first embodiment;

FIG. 2 is a block diagram of an auxiliary sensing and control system for semiconductor equipment, according to a second embodiment;

FIG. 3 is a flowchart of a sensing and control method for semiconductor equipment, according to an embodiment;

FIG. 4 is a block diagram illustrating the sensing and control method for semiconductor equipment, according to the first embodiment shown in FIG. 1; and

FIG. 5 is a block diagram illustrating the sensing and control method for semiconductor equipment, according to the second embodiment shown in FIG. 2.

### DETAILED DESCRIPTION OF THE EMBODIMENTS

Hereinafter, an auxiliary sensing and control system for semiconductor equipment, according to an embodiment, is described with reference to the drawings, thereby providing specific details for carrying out the inventive concept.

The terms “portion”, “block”, “logic”, or “module” used in the first and second embodiments described below may include a unit implemented in hardware, software, or firmware, and may be used interchangeably with terms, such as a logic, a logic block, a component, or a circuit. The “portion”, the “block”, the “logic” or “module” may be a component that is configured integrally or a minimum unit of the component that performs one or more functions or a part thereof. For example, according to an embodiment, the “unit”, the “block”, the “logic”, or the “module” may be implemented in the form of an application-specific integrated circuit (ASIC) or a field-programmable gate array (FPGA).

A program executed in the auxiliary sensing and control system for semiconductor equipment, according to an embodiment, may be implemented as a hardware component, a software component, and/or a combination of the hardware component and the software component. The program may be performed by any system capable of performing computer-readable instructions.

The software may include a computer program, code, instructions, or a combination of one or more thereof, and may configure a processing device to perform a desired operation or may independently or collectively command the processing device to perform the desired operation. The software may be implemented as a computer program that includes instructions stored in a computer-readable storage medium. Examples of the computer-readable storage medium include a magnetic storage medium (e.g., read-only memory (ROM), random-access memory (RAM), a floppy disk, and a hard disk), and an optical reading medium (e. g., a CD-ROM and a digital versatile disc (DVD)).

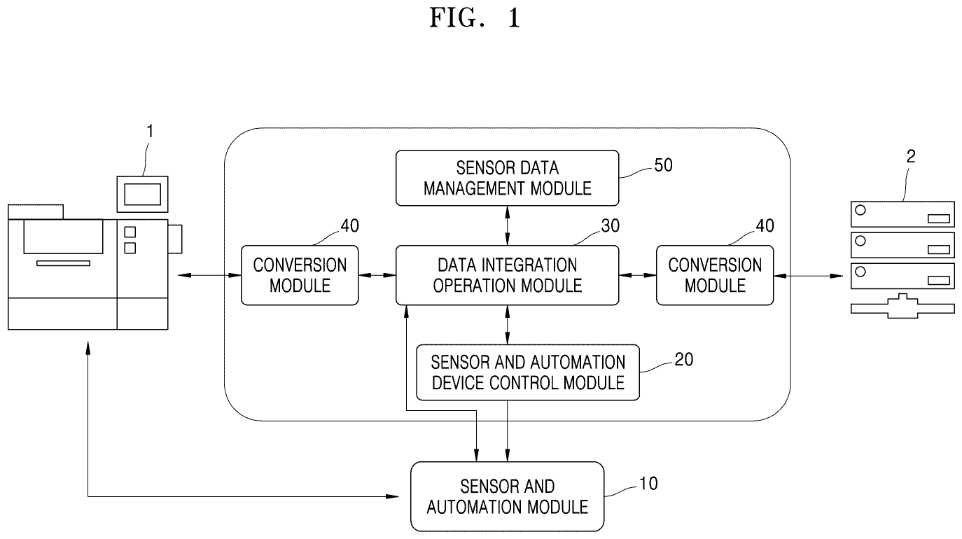

The first embodiment illustrated in FIG. 1 is described first. FIG. 1 is a block diagram of an auxiliary sensing and control system for semiconductor equipment, according to the first embodiment. An arrow shown in the drawing indicates a direction of communication. A bidirectional arrow refers to bidirectional communication. The information to be conveyed through the communication is described below.

The auxiliary sensing and control system for semiconductor equipment, according to the first embodiment, includes a system applied to equipment for semiconductor equipment communications standard 1 (SECS-I) communication based on serial interface (I/F) with a host system 2 and equipment for high-speed SECS message services (HSMS) communication based on transmission control protocol/Internet protocol (TCP/IP) with the host system 2, wherein the host system 2 identifies the process status of semiconductor equipment 1 and performs control corresponding to the identified process status. The auxiliary sensing and control system for semiconductor equipment is used for identifying and automating the process status of the semiconductor equipment 1. The term “automation” refers to a general-purpose concept where software or hardware, on behalf of an operator, is used to input instructions for controlling the semiconductor equipment 1, rather than having an operator directly input instructions for controlling the semiconductor equipment 1 by using an input device, such as a keyboard or a mouse, provided in the semiconductor equipment 1. Therefore, a control command may be issued by itself, such as active control. When a person operating the host system 2 analyzes trace data and transmits a control command to input the control command, the command may be received and necessary measures may be taken. A learned artificial intelligence (AI) system may be used for the active control.

The host system 2 includes a system that transmits and receives data from each piece of semiconductor equipment 1 through semiconductor equipment communications standard/generic equipment model protocol (SECS/GEM) or HSMS standard protocol, analyzes the collected data, and transmits the control command to the semiconductor equipment 1. The host system 2 performs a function of coordinating a status and an operation of each piece of semiconductor equipment 1 and instructs each piece of semiconductor equipment 1 to perform a process according to a process recipe. In addition, sensor data may be collected in real time to detect an abnormal status or analyze process quality and may be integrated with a fault detection and classification (FDC) system to monitor an equipment status and detect an abnormality early.

The SECS-I is a protocol based on RS-232C serial communication and is a protocol for exchanging data between semiconductor equipment and a host system. RS-232C is used to provide stable communication between equipment with a slow transmission speed, deliver data without errors using a relatively simple message structure, and transmit information, such as process control data, equipment status, and alerts. The RS-232C is mainly applied to old equipment with a certain operating life and is not used for new equipment.

On the other hand, SECS-II is a protocol that defines the content of a message to the upper layer of SECS-I and enables real-time monitoring and control of the status of the equipment and the process data through various messages between the equipment and the host system.

The auxiliary sensing and control system for semiconductor equipment, according to an embodiment, includes a sensor and automation module 10, a sensor and automation device control module 20, a data integration operation module 30, a conversion module 40, and a sensor data management module 50, as shown in FIG. 1.

The sensor and automation module 10 includes a sensor and an automation device.

The sensor measures the process status of the semiconductor equipment 1. The sensor for the semiconductor equipment 1 may include one or a combination of two or more of a temperature sensor, a pressure sensor, a gas sensor, a particle sensor, a vibration sensor, an optical sensor, a thickness measurement sensor, and a humidity sensor. An appropriate sensor is selected depending on the equipment.

A sensor that is not previously installed in the semiconductor equipment 1 may be added to the sensor installed in the sensor and automation module 10 or a sensor of the same type as the already installed sensor may be added to the sensor installed in the sensor and automation module 10 for more precise measurement.

The values measured by the sensor may be digitally converted by an analog-to-digital (A/D) conversion module.

The automation device included in the sensor and automation module 10 refers to a device that performs a semiconductor manufacturing process by operating the system on its own without human intervention. The automated device may include a device that automatically measures and optimizes process variables, detects process anomalies through a sensor and a data analysis system and makes real-time adjustments, or analyzes sensor data to predict equipment failures in advance and perform preventive measures. For example, when the temperature of the semiconductor equipment 1 is lower than a set value, physical control, such as raising the temperature, is performed by controlling the heating means provided in the semiconductor equipment 1. The software may also be used to convert the values measured by the sensor into a format suitable for transmission to the host system 2.

The sensor and automation device control module 20 is configured to control the sensor and automation module 10.

The sensor and automation device control module 20 may actively control the semiconductor equipment 1. The active control may refer to controlling the semiconductor equipment 1 by monitoring the status of the semiconductor equipment 1 in real time, analyzing the collected data, and issuing an optimal control command.

A signal for automatically controlling the semiconductor equipment 1 by using the automation device by analyzing the value measured by the sensor is generated in the sensor and automation device control module 20 and transmitted to the automation device of the sensor and automation module 10, and the automation device may perform the received command signal to physically control the semiconductor equipment 1.

While the sensor and automation device control module 20 receives and holds all SECS data moving between the semiconductor equipment 1 and the host system 2, the SECS data may be made into a DataFrame and transmitted to the sensor and automation module 10.

The DataFrame may be divided into Part #1 (head) and Part #2 (body). The SEND of Part #1 is the head of the SECS data transmitted by the semiconductor equipment 1, and the RECV of Part #1 is the head of the SECS data transmitted by the host system 2. The Part #2 of the DataFrame is body data of the Part #1 (SEND/RECV) head.

The sensor and automation module 10 implements the sensing and automation operations according to the received DataFrame, and the result of the sensing operation and the result of the automation operation are transmitted back to the data integration operation module 30.

The data integration operation module 30 transmits trace data of the semiconductor equipment 1 and data acquired by the automation device of the sensor and automation module 10 to the host system 2 and receives and processes the control signal of the host system 2.

The trace data refers to various operation and status data collected by the semiconductor equipment 1 and is generally stored in a time-series data format. The trace data is used to monitor and analyze the status, the performance, and the environment variables of the semiconductor equipment 1 in real time.

The trace data may be collected through a device, such as the sensor already installed in the semiconductor equipment 1, may be collected through the sensor of the sensor and automation module 10 (a sensor newly installed in the semiconductor equipment 1), or may be collected by a combination of the two sensors. When the semiconductor equipment 1 itself cannot provide the trace data, the trace data may be collected only by the sensor of the sensor and automation module 10.

Processing the control signal includes classifying, integrating, and if necessary, transforming the data for each signal.

The control signal of the host system 2 may include a signal for requesting the trace data and a signal for analyzing the trace data to control the semiconductor equipment 1.

The data integration operation module 30 may collect the trace data in a synchronous manner by transmitting and receiving traces of the semiconductor equipment 1 at regular intervals, and in an asynchronous manner by requesting and receiving the trace data at irregular intervals, when necessary.

The data integration operation module 30 may collect and store data received from the semiconductor equipment 1 and the sensor and automation module 10.

The term “buffer” refers to a device for temporarily storing data. In an embodiment, the data integration operation module 30 may function as a buffer.

The buffer may perform the following functions.

First, when the data processing speed of a transmitting device is different from the data processing speed of a receiving device, the data is temporarily stored without being transmitted at once to adjust the speed difference. For example, when data received by a high-speed network device is transmitted to a low-speed device, the buffer temporarily stores the data to prevent data loss.

Second, the buffer may retransmit or correct the data order based on the data stored in the buffer when data is lost or the order is erroneous.

Third, when a sudden increase in traffic occurs in the network, data may be stored in the buffer to alleviate congestion. The data is temporarily stored and then transmitted when the network becomes stable, thereby preventing network overload.

Fourth, transmitting the data stored in the buffer, when a temporary failure occurs during communication or when equipment is disconnected and reconnected, enables stable communication without data loss.

Fifth, when communication equipment receives or transmits multiple packets at the same time, the buffer sequentially stores and processes the packets, thereby increasing the efficiency of data transmission.

Since the number of pieces of the semiconductor equipment 1 is much greater than the number of host systems 2, the data may be temporarily stored in the data integration operation module 30 to function as the buffer described above.

The conversion module 40 interconverts the SECS-I signal and the HSMS signal, and interconverts signals between the HSMS and the HSMS. The SECS-I-based signal of the semiconductor equipment 1 is converted into an HSMS-based signal by the conversion module 40 and transmitted to the data integration operation module 30. The HSMS-based signal (a signal for controlling equipment) of the host system 2 is also converted into an SECS-I-based signal by the conversion mode 40 and transmitted to the data integration operation module 30.

A protocol conversion device may be used for converting the SECS-I signal into the HSMS signal, or the conversion may be performed using software. When converting the SECS-I signal to the HSMS signal using software, communication protocols may be switched without changing existing hardware.

The conversion module 40 enables HSMS communication without upgrading the communication module of the semiconductor equipment 1 or installing separate software in the semiconductor equipment 1. Thus, problems, such as slow speed and wired communication mode, which are disadvantages of SECS-I, may be tackled.

The sensor data management module 50 performs status variable identification (SVID) setting.

The SVID is a variable identifier used to monitor and control the status of the semiconductor equipment 1 in the semiconductor manufacturing process. The SVID is a concept included in the GEM standard and is used to transmit or request various information related to the status of the semiconductor equipment 1 to the host system 2. The GEM stands for generic equipment model and is an equipment automation standard designed based on the SECS communication standard. The host system 2 is used to automatically control the semiconductor equipment 1 and monitor the status of the semiconductor equipment 1 in real time.

The SVID is an ID for identifying a variable indicating a specific status to provide status information of the semiconductor equipment 1, and each variable is assigned a specific status, a condition, or the like. For example, the current temperature of the equipment, the pressure process step, and the like may be set to a separate ID.

Through the SVID, various statuses of the semiconductor equipment 1 may be monitored in real time by the host system 2. Thus, an abnormal status that can occur during the process may be quickly identified and necessary measures may be taken.

In an embodiment, various statuses and conditions measured or monitored by the existing sensor system of the semiconductor equipment 1 and the sensor and automation module 10 are set to respective IDs by the sensor data management module 50. Through this configuration, data measured by one piece of equipment may be given an appropriate ID, thereby efficiently transmitting the data to the host system 2.

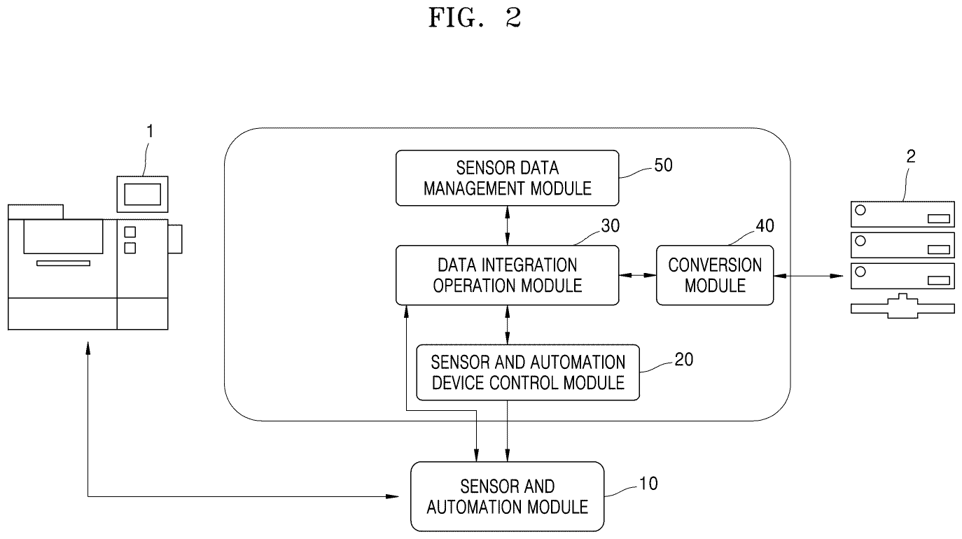

In the second embodiment, as shown in FIG. 2, the semiconductor equipment 1 is not provided with a device, such as a sensor capable of generating trace data.

In the second embodiment, compared to the first embodiment, the data integration operation module 30 collects trace data only from the sensor and automation module 10 and transmits the trace data to the host system 2.

Hereinafter, functions, operations, and effects of the respective components are be described with reference to the drawings, by describing a first embodiment and a second embodiment of a sensing and automation method for semiconductor equipment where, using the auxiliary sensing and control system for semiconductor equipment described above, the process status of the semiconductor equipment 1 is measured and the measured data is transmitted to the host system 2, and a control signal is transmitted from the host system 2 to the semiconductor equipment 1. The first embodiment is described first.

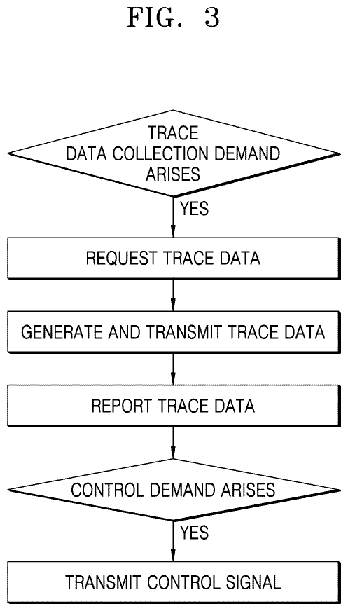

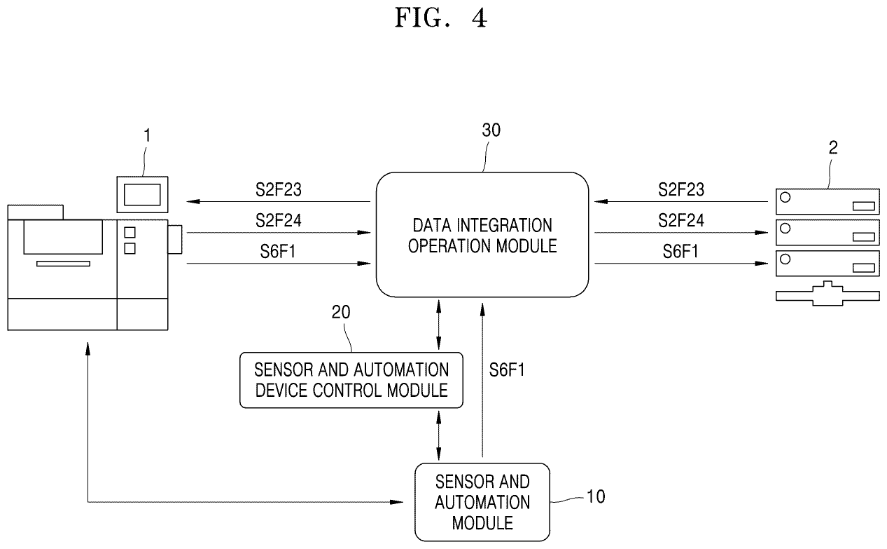

FIG. 3 is a flowchart of a sensing and control method for semiconductor equipment, according to an embodiment, and FIG. 4 is a block diagram illustrating the sensing and control method for semiconductor equipment, according to the first embodiment shown in FIG. 1.

The sensing and control method for semiconductor equipment, according to an embodiment, includes requesting trace data, generating and transmitting the trace data, and reporting the trace data, as shown in FIG. 3.

The requesting of the trace data includes transmitting, by the data integration operation module 30, a trace data request signal of the semiconductor equipment 1 when a trace data collection demand arises.

The transmitting of the trace request signal is performed by the data integration operation module 30 receiving the trace data request signal from the host system 2 or the data integration operations module 30 actively generating the trace data request signal.

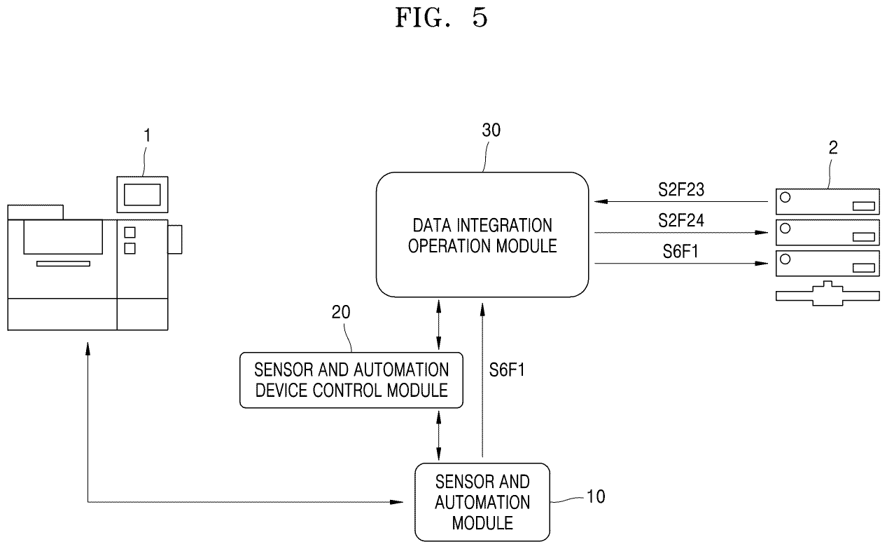

When the host system 2 requests the trace data from the data integration operation module 30, the trace data request is transmitted from the host system 2 to the data integration operation mode 30 in the form of S2F23 as shown in FIG. 4. Based on the received S2F23 signal, the data integration operation module 30 transmits the S2F23 signal to the semiconductor equipment 1 and the sensor and automation module 10 to request the trace data. When the semiconductor equipment 1 is not equipped with a sensor, the S2F23 signal is transmitted only to the sensor and automation module 10, as shown in FIG. 5.

The data integration operation module 30 transmits the S2F23 signal to the semiconductor equipment 1 and the sensor and automation module 10 even when the data integration operation module 30 actively generates a request for collecting the trace data.

The S2F23 (Stream 2, Function 23) signal may include a stream ID for collecting data, trace items, a sample interval, total samples, and the like. For example, the semiconductor equipment 1 requests to collect specific sensor data (e.g., temperature and pressure) 10 times per second.

The generating and transmitting of the trace data includes receiving the trace data request signal S2F23 to generate the trace data and transmitting the trace data to the data integration operation module 30.

When the semiconductor equipment 1 or the sensor and automation module 10 receives the S2F23 signal from the data integration operation module 30, the S2F24 signal is transmitted as a response signal, as shown in FIG. 4 or FIG. 5, wherein the S2F24 signal includes a signal that informs the host system 2 that the semiconductor equipment 1 successfully processed the request for the S2F23 signal.

The S2F24 signal includes a code (ACK code) indicating a request processing result, which may include success (0), request rejection (1), a request being erroneous (2), equipment not supporting traces (3).

When the semiconductor equipment 1 or the sensor and automation module 10 can perform a command (e.g., the type of measurement, the intervals, the total number of pieces of data) of the received S2F23 signal, the trace data is generated according to the S2F23 signal and transmitted to the data integration operation module 30.

In the process of generating the trace data, the SVID set by the sensor data management module 50 is used. As described above, the SVID is an ID for identifying a variable indicating a specific status to provide status information of the semiconductor equipment 1, wherein each variable is assigned a specific status, a condition, or the like. For example, the current temperature of the equipment, the pressure process step, and the like may be set to a separate ID.

The reporting of the trace data includes transmitting the trace data received by the data integration operation module 30 to the host system 2.

When the data integration operation module 30 transmits the trace data to the host system 2, the response S6F1 (Stream 6, Function 1) of first trace data is transmitted to the host system 2 in synchronization with the semiconductor equipment 1.

When the measurement interval of the trace data requested by the host system 2 is different from the data interval that can be measured by the semiconductor equipment 1 and the sensor and automation module 10, the data integration operation module 30 may take necessary measures.

For example, when the host system 2 requests temperature data 100 times at 1-second intervals but the semiconductor equipment 1 can measure the temperature at 2-second intervals, the data integration operation module 30 generates 1-second interval data by using the data measured at the 2-second intervals and transmits the data to the host system 2. The semiconductor equipment 1 receives a command and measures 50 pieces of data in the order of 0 seconds, 2 seconds, 4 second, and the like. The data integration operation module 30 fills the data corresponding to odd seconds, such as 1 second, 3 seconds, 5 seconds, and the like, with the same value as the data of the previous 1 second and transmits 100 pieces of data to the host system 2. When 0 second data is 100, 2 second data is 98, 4 second data is 99, and the like, 1 second data is 100, 3 second data is 98, 5 second data is 99, and the like. In this way, the data of the unmeasured time may be filled.

The transmitting of the control signal includes transmitting, by the data integration operation module 30, the control signal when a control demand arises as a result of receiving and analyzing the trace data by the host system 2 or the data integration operation module 30.

The data integration operation module 30 receives the control signal from the host system 2 or actively generates the control signal.

The sensor and automation device control module 20 receives the control signal from the data integration operation module 30, controls the automation device of the sensor and automation module 10 based on the received control signal, and transmits the control signal to the semiconductor equipment 1 to perform automation control.

In the semiconductor equipment 1 receiving the data request signal from the data integration operation module 30, the trace data is generated by the existing sensor (not shown) already installed in the semiconductor equipment 1, the generated trace data is transmitted as a serial I/F-based SECS-I communication signal, and the transmitted data is input to the conversion module 40.

The conversion module 40 converts the SECS data into an HSMS signal and transmits the HSMS signal to the data integration operation module 30, and the data integration operation module 30 transmits the trace data to the host system 2 through the conversion module 40.

The host system 2 checks the received trace data and transmits the control signal of the semiconductor equipment 1, when necessary, which is transmitted to the data integration operation module 30 through the conversion module 40, and delivers the received data to the sensor and automation device control module 20.

The trace data generated by the sensor and automation module 10 is also transmitted to the host system 2 through the data integration operation module 30. However, since the sensor and automation module 10 can be configured to perform communication through the HSMS-based signal, the trace data may be transmitted from the conversion module 40 to the host system 2 without a separate conversion.

The communication related to the trace data request and reply between the semiconductor equipment 1 and the host system 2 described above may be delivered in a synchronous/asynchronous manner.

When the semiconductor equipment 1 does not generate the trace data by itself as shown in FIG. 2, the S2F23 signal is transmitted only to the sensor and automation module 10 when the data integration operation module 30 requests the trace data as shown in FIG. 5, and the sensor and automation module 10 generates the trace data and transmits the same to the data integration operation module 30.

Although two preferred embodiments of the auxiliary sensing and control system for semiconductor equipment according to the inventive concept and the sensing and control method using the same have been described above to provide specific details for carrying out the inventive concept, the technical idea of the inventive concept is not limited to the described embodiments, and various types of auxiliary sensing and control systems for semiconductor equipment and sensing and control methods using the same can be embodied within a range not contrary to the technical idea of the inventive concept.

While the inventive concept has been particularly shown and described with reference to embodiments thereof, it will be understood that various changes in form and details may be made therein without departing from the spirit and scope of the following claims.

What is claimed is:

1. An auxiliary sensing and control system for semiconductor equipment, the system comprising:
a sensor and automation module comprising an automation device and a sensor additionally installed in the semiconductor equipment;
a sensor and automation device control module configured to control the sensor and automation module; and
a data integration operation module configured to transmit trace data of the semiconductor equipment and data acquired by the automation device of the sensor and automation module to a host system, and to receive and to process a control signal of the host system.

2. The auxiliary sensing and control system for the semiconductor equipment of claim 1, wherein the sensor and automation device control module is further configured to receive and hold a value of semiconductor equipment communications standard (SECS) data converted into a DataFrame.

3. The auxiliary sensing and control system for the semiconductor equipment of claim 2, wherein the sensor and automation device control module is further configured to control the sensor and automation module based on the received DataFrame, and to receive a control result of the sensor and automation module and to return the control result to the data integration operation module.

4. The auxiliary sensing and control system for the semiconductor equipment of claim 3, further comprising a conversion module configured to interconvert an SECS signal and a high-speed SECS message services (HSMS) signal.

5. The auxiliary sensing and control system for the semiconductor equipment of claim 1, further comprising a conversion module configured to interconvert an SECS signal and an HSMS signal.

6. The auxiliary sensing and control system for the semiconductor equipment of claim 1, further comprising a sensor data management module configured to manage and to operate a status variable identification (SVID) and a newly registered SVID of the semiconductor equipment.

7. The auxiliary sensing and control system for the semiconductor equipment of claim 3, further comprising a sensor data management module for managing and operating an SVID and a newly registered SVID of the semiconductor equipment.

8. The auxiliary sensing and control system for the semiconductor equipment of claim 1, wherein the semiconductor equipment and the host system perform synchronous communication for transmitting and receiving the trace data of the semiconductor equipment at regular intervals or irregular asynchronous communication.

9. An auxiliary sensing and control system for semiconductor equipment, the system comprising:
a sensor and automation module comprising an automation device and a sensor additionally installed in the semiconductor equipment;
a sensor and automation device control module configured to control the sensor and automation module;
a data integration operation module configured to transmit trace data of the semiconductor equipment and data acquired by the sensor and the automation device of the sensor and automation module to a host system, and to receive and to process a control signal of the host system;
a conversion module configured to convert a semiconductor equipment communications standard (SECS) signal and a high-speed SECS message services (HSMS) signal; and
a sensor data management module configured to manage and operating a status variable identification (SVID) and a newly registered SVID of the semiconductor equipment,
wherein the sensor and automation device control module is further configured to receive and to hold a value obtained by converting the SECS data into a DataFrame, to control the sensor and automation module based on the received DataFrame, and to receive a control result of the sensor and automation module and to return the control result to the data integration operation module, and
the semiconductor equipment and the host system perform synchronous communication for transmitting and receiving the trace data of the semiconductor equipment at regular intervals, or perform irregular asynchronous communication.

10. The auxiliary sensing and control system for the semiconductor equipment of claim 9, wherein the conversion module is further configured to interconvert the HSMS signal and the HSMS signal.

11. The auxiliary sensing and control system for the semiconductor equipment of claim 9, wherein a number of pieces of the semiconductor equipment is greater than a number of host systems.

12. The auxiliary sensing and control system for the semiconductor equipment of claim 9, wherein the trace data is collected through the sensor of the sensor and automation module.

13. A sensing and control method for semiconductor equipment, the method comprising:
requesting trace data, in which a data integration operation module transmits a trace data request signal of the semiconductor equipment;
generating and transmitting trace data, wherein the trace data is generated upon receiving the trace data request signal, and transmitted to the data integration operation module; and
reporting the trace data wherein the data integration operation module transmits the received trace data to a host system.

14. The sensing and control method for the semiconductor equipment of claim 13, wherein the data integration operation module receives the trace data request signal from the host system or actively generates the trace data request signal.

15. The sensing and control method for the semiconductor equipment of claim 13, wherein the trace data is generated by the semiconductor equipment or the sensor and automation module.

16. The sensing and control method for the semiconductor equipment of claim 15, wherein the trace data generated by the semiconductor equipment is converted into a high-speed SECS message services (HSMS) signal by a conversion module.

17. The sensing and control method for the semiconductor equipment of claim 13, further comprising transmitting, by the data integration operation module, a control signal.

18. The sensing and control method for the semiconductor equipment of claim 17, wherein the data integration operation module receives the control signal from the host system or actively generates the control signal.

19. The sensing and control method for the semiconductor equipment of claim 17, wherein the sensor and automation device control module receives the control signal from the data integration operation module and controls an automation device of the sensor and automation module, based on the received control signal.

20. The sensing and control method for the semiconductor equipment of claim 13, wherein the sensor and automation control module converts SECS data into a DataFrame for transmission.
